(19) United States
(12) Patent Application Publication
(10) Pub. No.: US 2004/0060514 A1
(43) Pub. Date: Apr. 1, 2004

(54) Gas distribution showerhead

(75) Inventors: Karthik Janakiraman, San Jose, CA (US); Nitin Ingle, Campbell, CA (US); Zheng Yuan, Fremont, CA (US); Steven Gianoulakis, Pleasanton, CA (US)

Correspondence Address: Applied Materials, Inc., Legal Affairs Department, M/S 2061, P.O. Box 450A, Santa Clara, CA, 95052, US

(73) Assignee: APPLIED MATERIALS, INC. A Delaware corporation, Santa Clara, CA

(21) Appl. No.: 10/674,569

(22) Filed: Sep. 29, 2003

Related U.S. Application Data
(63) Continuation-in-part of application No. 10/057,280, filed on Jan. 25, 2002.

(51) Int. Cl. C23C 16/00

(52) U.S. Cl. 118/715

(57) ABSTRACT

A gas distribution showerhead is designed to allow deposition of uniformly thick films over a wide range of showerhead-to-wafer spacings. In accordance with one embodiment of the present invention, the number, width, and/or depth of orifices inlet to the faceplate are reduced in order to increase flow resistance and thereby elevate pressure upstream of the faceplate. This elevated upstream gas flow pressure in turn reduces variation in the velocity of gas flowed through center portions of the showerhead relative to edge portions, thereby ensuring uniformity in thickness of film deposited on the edge or center portions of the wafer.

### CROSS REFERENCE TO RELATED APPLICATION

The instant application claims priority as a continuation-in-part of U.S. nonprovisional patent application Ser. No. 10/057,280 filed Jan. 25, 2002, which is incorporated by reference herein for all purposes.

### BACKGROUND OF THE INVENTION

High temperature chemical vapor deposition (CVD) processes have encountered widespread use in the semiconductor industry. FIG. 1A shows a simplified cross-sectional view of a conventional apparatus for performing high temperature chemical vapor deposition. For purposes of illustration, FIG. 1A and other figures of present application are not drawn to scale.

Apparatus 100 comprises wafer support structure 104 housed within deposition chamber 105. A wafer 102 may be placed upon support structure 104 during substrate processing.

Gas distribution showerhead 106 is positioned above wafer 102 and is separated from wafer 102 by gap Y. The magnitude of gap Y for a particular application may be controlled by adjusting the height of wafer support structure 104 relative to showerhead 106. For example, during conventional deposition of undoped silicate glass (USG) materials, gap Y may be greater than about 300 mils.

Gas distribution showerhead 106 comprises process gas inlet 108 in fluid communication with blocker plate 110 having apertures 112. Gas distribution face plate 114 is positioned downstream of blocker plate 110. Face plate 114 receives a flow of process gas from blocker plate 110 and flows this gas through holes 116 to wafer 102. Layer 118 of deposited material is formed over wafer 102 as a result of the flow of process gases.

FIG. 1B shows a bottom perspective view of the conventional gas distribution face plate 114 of FIG. 1A. Holes 116 of face plate 114 are distributed over the surface of the face plate. FIG. 1B shows only one example of the distribution of holes 116 on a face plate, and many other arrangements of holes on a face plate are possible.

Referring again to FIG. 1A, the role of blocker plate 110 is to coarsely distribute incoming process gas stream 120 over the inlet side 114a of face plate 114. Face plate 114 in turn distributes the gas stream to produce a uniform, finely distributed flow that is exposed to wafer 102. As a result of exposure to this finely-distributed flow of processing gas, high quality layer 118 of deposited material is formed over wafer 102.

The conventional high temperature deposition apparatus shown in FIGS. 1A-1B is effective to create structures on the surface of a semiconductor wafer. One type of structure formed by high temperature CVD is shallow trench isolation (STI). FIG. 2 shows an enlarged cross-sectional view of wafer 200 bearing semiconductor structures 202 such as active transistors. Adjacent active semiconductor devices 202 are electronically isolated from one another by STI structures 204 comprising trenches filled with dielectric material such as undoped silicate glass (USG).

STI structures are formed by masking and etching exposed regions of a wafer to create trenches. The mask is then removed and USG is deposited over the wafer using a high temperature process, including within the trenches. USG deposited outside of the trenches may subsequently be removed by etching or chemical mechanical polishing (CMP) to reveal the final STI structures.

The conventional apparatus shown in FIGS. 1A-1B has been successfully utilized to deposit materials such as USG at high temperatures, for STI and other applications. However, improvements in the design of the high temperature deposition apparatus are desirable. For example, it is known that faster deposition rates may be achieved by spacing the showerhead closer to the wafer. A faster deposition rate will enhance throughput of the deposition apparatus, thereby enabling an operator to more quickly recoup costs of purchasing and maintaining the device.

However, closer spacing of the wafer relative to the showerhead can result in the deposited material exhibiting uneven topography visible as spotting or streaking on the wafer. The topography of material deposited at such close wafer-to-showerhead spacings may reflect the location of holes on the faceplate.

FIGS. 3A-3B are photographs illustrating the results of deposition of material at close wafer to faceplate spacings utilizing a conventional apparatus. FIG. 3A is a photograph showing a wafer bearing a USG film deposited from a conventional showerhead with a face plate-to-wafer spacing of 75 mils. The wafer of FIG. 3A shows significant spots and streaking.

FIG. 3B is a photograph showing a wafer bearing a USG film deposited from a conventional showerhead with a face plate-to-wafer spacing of 50 mils. The wafer of FIG. 3B shows even more pronounced spotting and streaking than the wafer of FIG. 3A.

Accordingly, methods and structures permitting application of processing gases at a close proximity to the surface of a substrate are desirable.

### SUMMARY OF THE INVENTION

Embodiments of gas distribution showerheads and methods in accordance with the present invention allow deposition of uniformly thick films over a wide range of showerhead-to-wafer spacings. In accordance with one embodiment of the present invention, the number, width, and/or depth of orifices inlet to the faceplate may be reduced in order to increase flow resistance and thereby elevate pressure upstream of the faceplate. This elevated upstream gas flow pressure in turn reduces variation in the velocity of gas flowed through center portions of the showerhead relative to edge portions, thereby ensuring uniformity in thickness of film deposited on the edge versus center portions of the wafer.

An embodiment of a method of depositing on a semiconductor wafer a layer of material having a center-to-edge thickness variation of 3% or less, comprises, providing a gas distribution faceplate having a thickness and defining a number of inlet orifices having a width and a depth. At least one of the orifice number, width, and depth are configured to create a uniform pressure drop of between about 0.8 and 1 Torr as gas is flowed through edge and center regions of the faceplate. A semiconductor wafer is provided separated from the gas distribution faceplate by a gap. Gas is flowed through the faceplate body and across the gap to deposit the layer of material on the wafer.

An embodiment of a gas distribution face plate in accordance with the present invention comprises a face plate body having a thickness defining a number of inlet orifices having a width and a depth. At least one of the number, the width, and the depth are configured to create a uniform pressure drop of between about 0.8 and 1 Torr across edge and center regions of the faceplate as gas is flowed through the inlet orifices. A thickness of material deposited at an edge of a wafer varies by 3% or less from a thickness of material deposited at a center of the wafer, when the wafer is separated from the face plate by a gap of between about 75 and 450 mils.

An embodiment of a method of promoting deposition of material of uniform center-to-edge thickness on a semiconductor wafer, comprises, constricting a flow of deposition gas through a gas distribution faceplate. A resulting pressure drop across the faceplate creates a low pressure region over a wafer, with gas velocities in the low pressure region over a wafer center and a wafer edge sufficiently uniform to result in deposition of a layer of material having a center-to-edge thickness variation of 3% or less.

These and other embodiments of the present invention, as well as its features and some potential advantages are described in more detail in conjunction with the text below and attached figures.

### BRIEF DESCRIPTION OF THE DRAWINGS

FIG. 1A is a simplified cross-sectional view of a conventional high temperature deposition system.

FIG. 1B is a bottom perspective view of the face plate of the conventional gas distribution showerhead of the system of FIG. 1A.

FIG. 2 shows a cross-sectional view of a conventional shallow trench isolation structure.

FIG. 3A is a photograph showing a wafer bearing a USG film deposited from a conventional showerhead with a face plate-to-wafer spacing of 75 mils.

FIG. 3B is a photograph showing a wafer bearing a USG film deposited from a conventional showerhead with a face plate-to-wafer spacing of 50 mils.

FIG. 4A is a simplified cross-sectional view of a high temperature deposition system in accordance with one embodiment of the present invention.

FIG. 4B is a top view of one embodiment of a face plate for a gas distribution showerhead in accordance with the present invention.

FIG. 4C is an underside view of one embodiment of a face plate for a gas distribution showerhead in accordance with the present invention.

FIG. 4D is an enlarged cross-sectional view of the face plate of FIGS. 4A-4B.

FIG. 5A is a photograph showing a wafer bearing a USG film deposited from a showerhead in accordance with an embodiment of the present invention with a face plate-to-wafer spacing of 75 mils.

FIG. 5B is a photograph showing a wafer bearing a USG film deposited from a showerhead in accordance with an embodiment of the present invention with a face plate-to-wafer spacing of 50 mils.

FIG. 6A is plan view of a composite face plate bearing both holes and elongated slots.

FIG. 6B is a photograph showing a wafer bearing a USG film deposited from a showerhead having a composite hole/slot configuration, at a face plate-to-wafer spacing of 75 mils.

FIG. 6C is a photograph showing a wafer bearing a USG film deposited from a showerhead having a composite hole/slot configuration, at a face plate-to-wafer spacing of 50 mils.

FIGS. 7A-7D show simplified plan views of face plates in accordance with alternative embodiments of the present invention bearing different patterns of elongated slots.

FIG. 8 plots deposition rate versus face plate-to-wafer spacing for USG deposition at different temperatures and pressures.

FIG. 9 plots deposition rate over a broad range of face plate-to-wafer spacings.

FIG. 10 plots % film shrinkage and wet etch selectivity versus face plate-to-wafer spacing for USG deposition processes at different temperatures and pressures.

FIGS. 11A and 11B show photographs of cross-sections of shallow trench isolation structures formed by high temperature USG deposition utilizing a conventional showerhead and a showerhead in accordance with the present invention, respectively.

FIG. 12 plots calculated added mass flow versus distance from the center of the wafer for two face plate-to-wafer spacings.

FIG. 13 shows a simplified cross-sectional view of an alternative embodiment of a high temperature deposition system in accordance with the present invention.

FIG. 14 plots calculated added mass flow versus distance from the center of the wafer for three different face plate profiles.

FIG. 15A shows a simplified cross-sectional view illustrating the flow of gases through a conventional gas distribution faceplate featuring outlet orifices.

FIG. 15B shows a simplified cross-sectional view illustrating the flow of gas through a gas distribution faceplate in accordance with an embodiment of the present invention featuring orifices of reduced size.

FIG. 16 plots the ratio of the thickness at the edge and center versus wafer to faceplate spacing for showerheads having two different hole diameters.

FIG. 17A shows a simplified and enlarged cross-sectional view of an outlet portion of a conventional faceplate.

FIG. 17B shows a simplified and enlarged cross-sectional view of an outlet portion of an embodiment of a faceplate in accordance with the present invention.

FIG. 18 shows a cross-sectional view of one embodiment of a faceplate in accordance with the present invention.

FIG. 19 plots the pressure drop across the faceplate shown in FIG. 18 versus the depth of the top hole, for two different faceplate designs.

FIG. 20A plots pressure drop versus the number of inlet orifices for a face plate design.

FIG. 20B plots gas velocity at the top of a slot versus the number of inlet.

FIGS. 21A-N show uniformity maps of wafers bearing layers deposited utilizing a conventional low resistance faceplate, and deposited utilizing a higher resistance faceplate in accordance with an embodiment of the present invention.

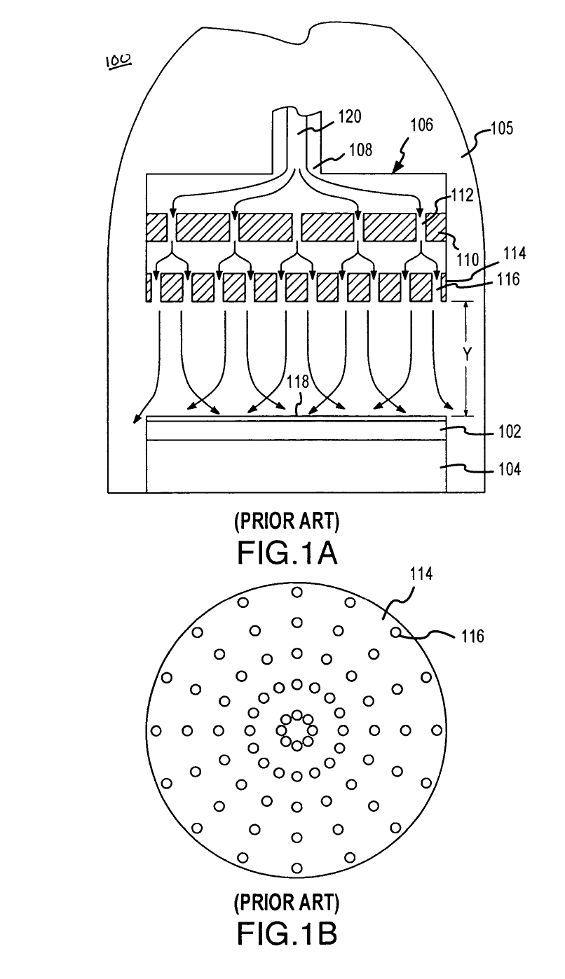

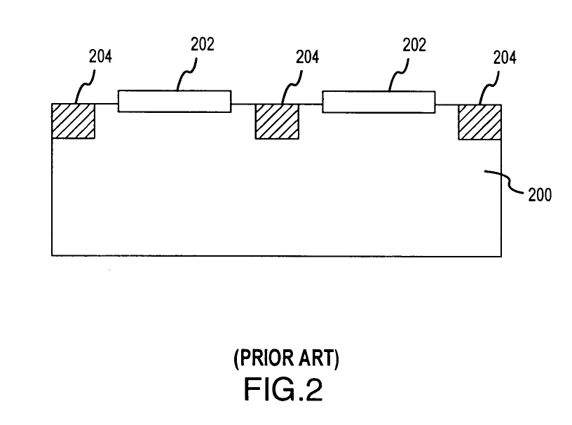

### DESCRIPTION OF THE SPECIFIC EMBODIMENTS

A gas distribution showerhead is designed to allow deposition of films of uniform thickness over a wide range of showerhead-to-wafer spacings. In accordance with one embodiment of the present invention, the configuration of orifices in the faceplate are reduced to increase flow resistance and thereby elevate pressure in the region immediately upstream of the faceplate. This elevated upstream gas flow pressure in turn reduces variation in the velocity of gas flowed through different portions (i.e., edge vs. center) of the showerhead, thereby ensuring uniformity in thickness of the film deposited in those regions.

A. Slotted Faceplate

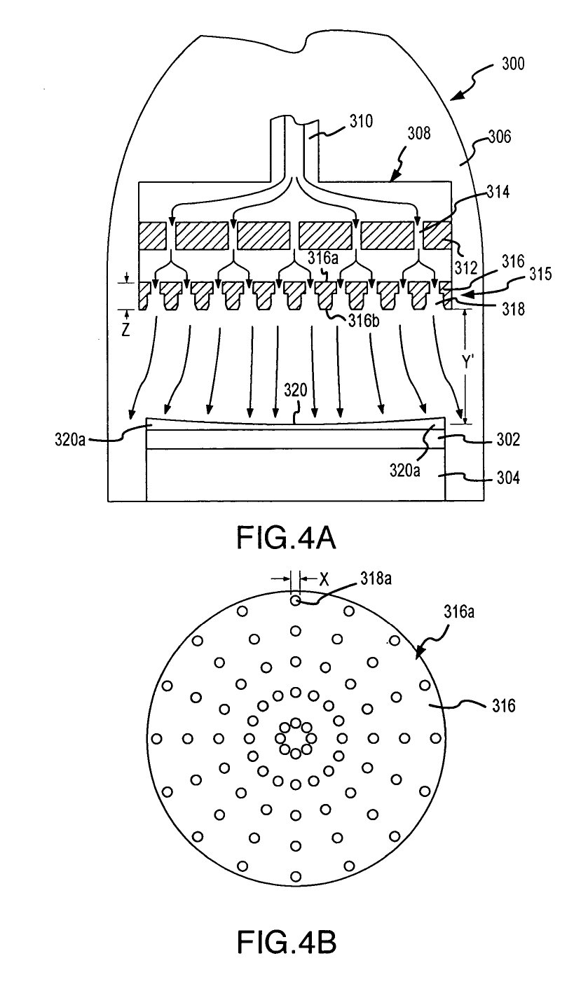

FIG. 4A shows a simplified cross-sectional view of one embodiment of a chemical vapor deposition system in accordance with the present invention. Apparatus 300 comprises wafer 302 in contact with wafer support structure 304 and housed within deposition chamber 306. Gas distribution showerhead 308 is positioned above wafer 302 and is separated from wafer 302 by gap Y′.

Gas distribution showerhead 308 comprises process gas inlet 310 in fluid communication with blocker plate 312 having apertures 314. Gas distribution face plate 316 having a body 315 of thickness Z is positioned downstream of blocker plate 312. Face plate 316 receives a flow of process gas from blocker plate 312 and flows this gas through apertures 318 in body 315 to wafer 302.

For purposes of illustration of the entire deposition apparatus, FIG. 4A is simplified to show apertures 318 having a constant cross-sectional profile. However, U.S. Pat. No. 4,854,263, commonly assigned to the assignee of the instant application, discloses the value of face plate apertures exhibiting an increase in cross-section transverse to the direction of gas flow.

FIG. 4B is a top (gas inlet) view of one embodiment of face plate 316 for a gas distribution showerhead in accordance with the present invention. FIG. 4C is an underside (gas outlet) view of one embodiment of face plate 316 for a gas distribution showerhead in accordance with the present invention.

As shown in FIG. 4B, gas inlet side 316a of face plate 316, receiving a flow of the coarsely distributed process gas from the blocker plate, includes a plurality of discrete holes 318a of diameter X. As shown in FIG. 4C, gas outlet side 316b of face plate 316, conveying the finely distributed process gas from the faceplate to the wafer, includes a plurality of continuous elongated slots 318b of length L. Elongated slots 318b may receive a gas flow from more than one discrete hole 318a. It has been found that provision of elongated slots having a length L of at least one-half the thickness Z of face plate 316, allows face plate 316 to be positioned close to the surface of the wafer without causing deposited material to exhibit unwanted topographical features such as spots and streaking.

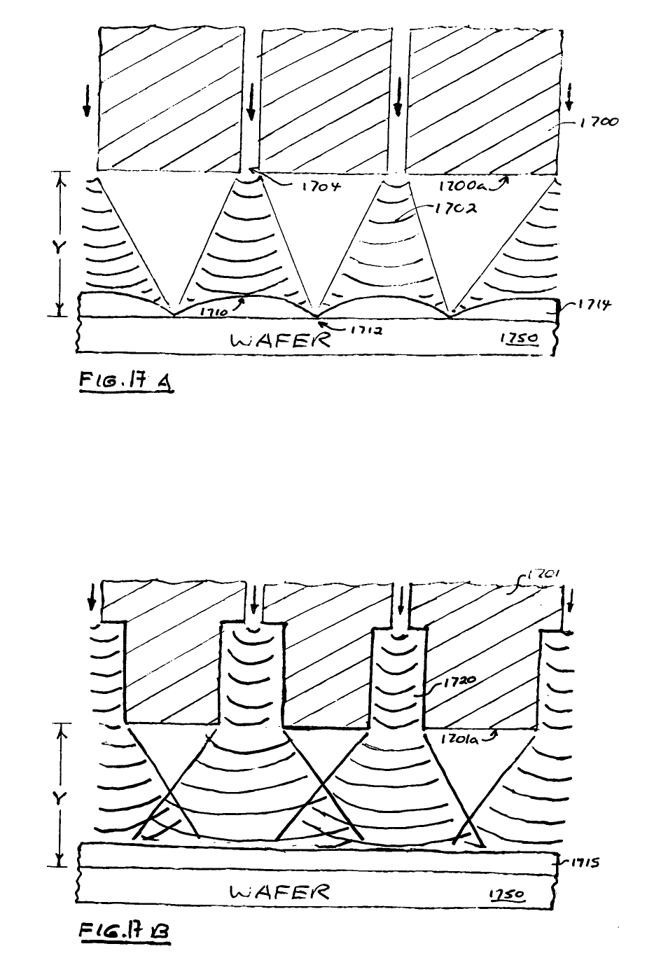

One source of variation in the thickness of films deposited utilizing conventional showerheads at close faceplate-to-wafer spacings is variation in gas velocity. Specifically, portions of the wafer proximate to faceplate openings will experience gas traveling at higher velocities than portions of the wafer distal from faceplate openings. This effect is shown in FIG. 17A, which shows a simplified cross-sectional view of an outlet portion 1700a of a conventional faceplate 1700, wherein isovelocity lines 1702 diminish at lateral distances from the position of the outlet orifices 1704. The location of these isovelocity lines 1702 would in turn correspond to localized peaks 1710 and troughs 1712 of film 1714 exhibiting different thicknesses when deposited on wafer 1750.

The profiles of gas velocity and thickness of deposited material shown in FIG. 17A may be contrasted with those shown in FIG. 17B, which corresponds to a simplified cross-sectional view of an embodiment of a faceplate 1701 in accordance with the present invention. Specifically, the presence of slots 1720 on the outlet portion 1701 a of the faceplate 1701 allows azimuthal diffusion of the flowed gas to commence prior to the gas exiting the faceplate. This additional azimuthal diffusion afforded by the presence of slots 1720 serves to even-out the velocity distribution of gases reaching the wafer surface, promoting deposition of film 1715 of uniform thickness.

As discussed in detail below, in certain embodiments it may be advantageous to ensure a pressure drop of a certain magnitude across the inlet and outlet portions of the faceplate, thereby ensuring homogenous flow velocity between edge and center portions of the faceplate. Accordingly, FIG. 4D shows an enlarged cross-sectional view of the face plate of FIGS. 4A-4C. FIG. 4D shows that for the particular embodiment illustrated, cross-sectional width X of holes 318a on flow inlet portion 316a are substantially more narrow than cross-sectional width X′ of elongated slots 318b on flow outlet portion 316b. Embodiments of the present invention may utilize elongated face plate slots having a ratio of X′/X of 2.25 or greater.

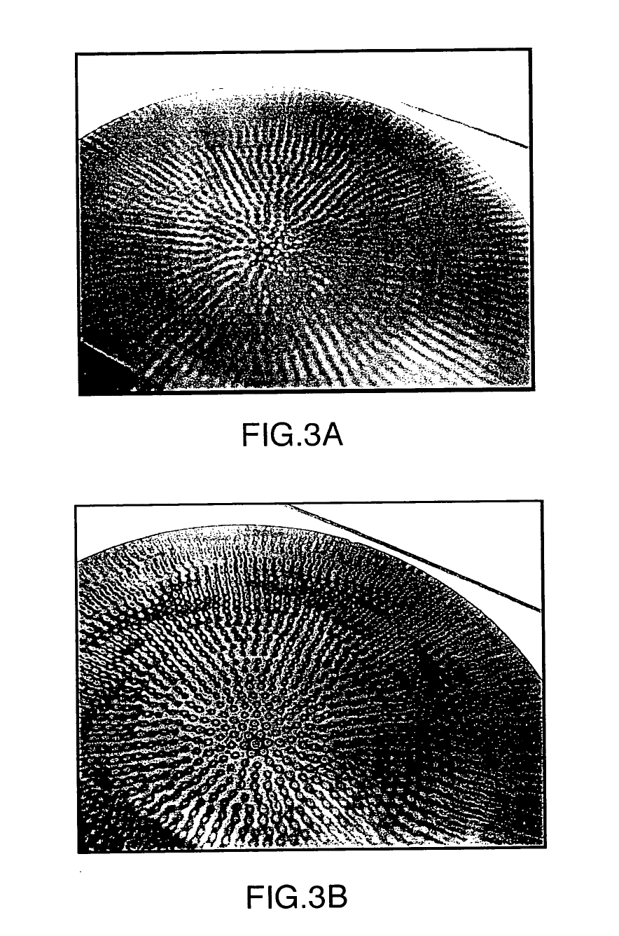

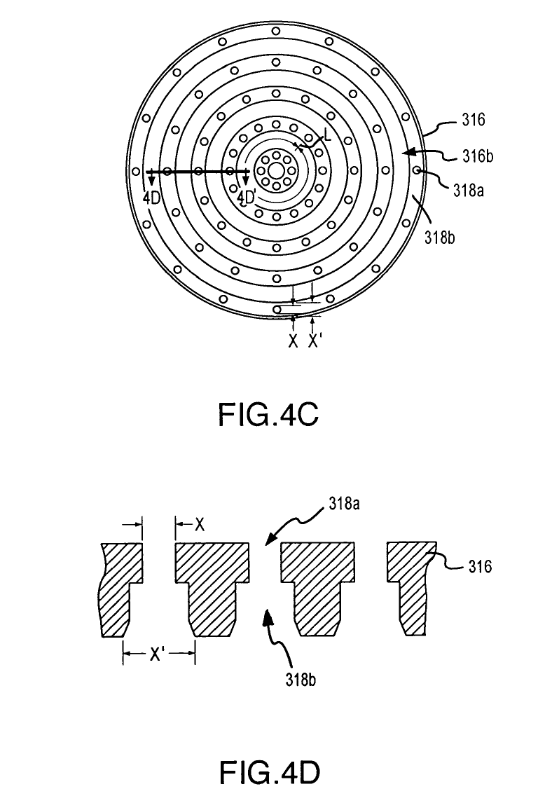

FIGS. 5A-5B are photographs illustrating the results of deposition of material in accordance with embodiments of the present invention. FIG. 5B is a photograph showing a wafer bearing a USG film deposited from a showerhead in accordance with an embodiment of the present invention, with a face plate-to-wafer spacing of 75 mils. The wafer of FIG. 5A exhibits substantially less spotting and streaking than the wafer resulting from deposition at the same spacing utilizing a conventional showerhead, shown in FIG. 3A.

FIG. 5B is a photograph showing a wafer bearing a USG film deposited from a showerhead in accordance with an embodiment of the present invention with a face plate-to-wafer spacing of 50 mils. The wafer of FIG. 5B exhibits substantially less spotting than the wafer resulting from deposition at the same spacing utilizing a conventional showerhead, shown in FIG. 3B.

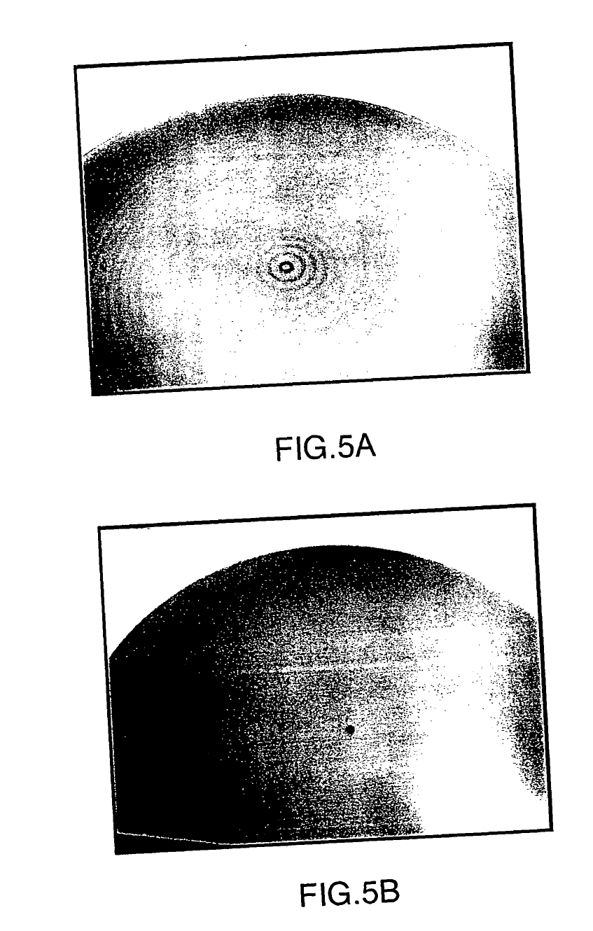

During development of the present invention, a composite face plate bearing both conventional holes and elongated slotted openings was utilized to deposit USG on a wafer. FIG. 6A shows a simplified plan view of this composite showerhead 450, which comprises first region 452 including conventional holes 454, and also comprises second region 456 including elongated slots 458 in accordance with embodiments of the present invention.

FIG. 6B is a photograph showing a wafer bearing a USG film deposited from the composite showerhead of FIG. 6A at a face plate-to-wafer spacing of 75 mils. FIG. 6C is a photograph showing a wafer bearing a USG film deposited from a showerhead having a composite hole/slot configuration, at a face plate-to-wafer spacing of 50 mils. Both FIGS. 6B and 6C reveal that material 402 deposited through the elongated slots exhibits substantially smoother topography than material 400 deposited from the conventional holes of the composite face plate.

While the above figures illustrate a showerhead bearing a plurality of continuous, concentrically oriented slots on its outlet side, this particular configuration is not required by the present invention. Other configurations of elongated slots could be employed, and the showerhead would remain within the scope of the present invention.

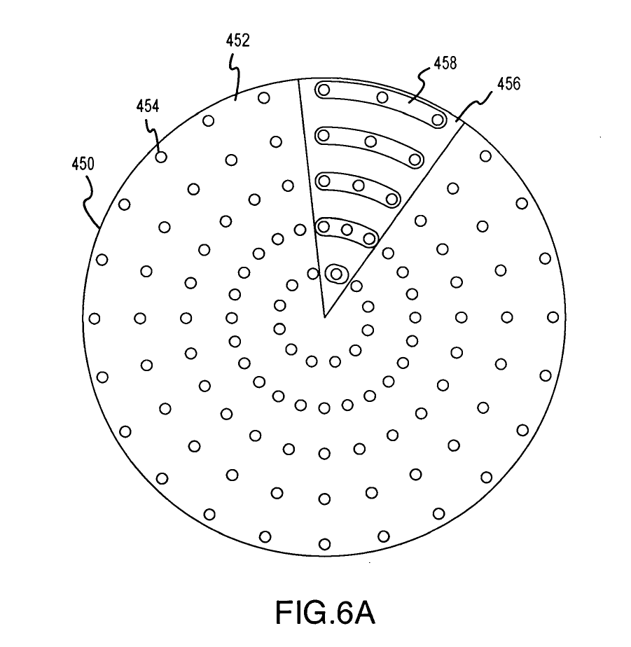

FIGS. 7A-7D show simplified bottom views of the outlet portion of a variety of alternative embodiments of gas distribution face plates in accordance with the present invention, each bearing different orientations of elongated slots. Face plate outlet portion 660 of FIG. 7A bears a plurality of non-continuous slots 662 oriented in a circumferential direction. Face plate outlet portion 664 of FIG. 7B bears a plurality of non-continuous slots 466 oriented in a radial direction. Face plate outlet portion 668 of FIG. 7C bears a plurality of non-continuous slots 670 that are exclusively oriented neither concentrically nor in a radial direction. Face plate outlet portion 672 of FIG. 7D bears a plurality of non-continuous slots 674 in combination with conventional holes 676.

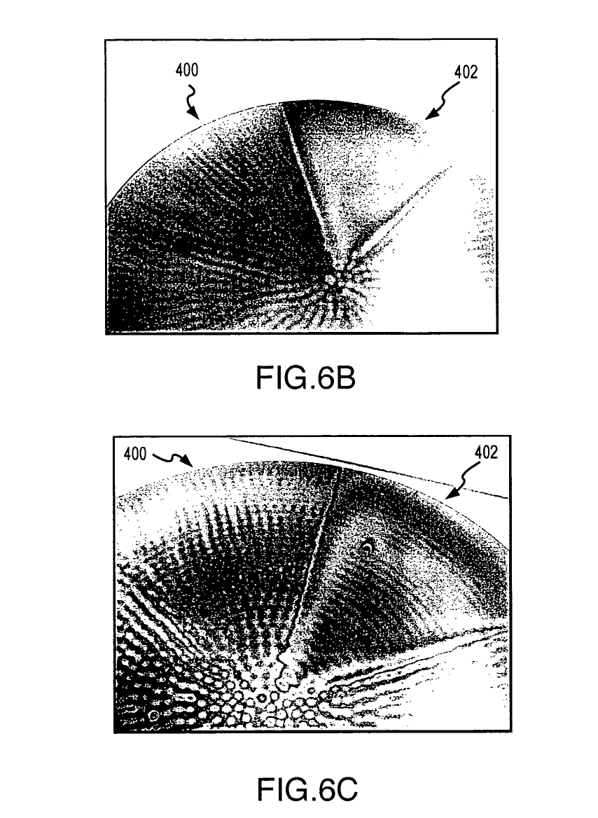

Embodiments of apparatuses and methods in accordance with the present invention offer a number of benefits. For example, FIG. 8 plots deposition rate versus face plate-to-wafer spacing for USG deposition processes at different temperatures. FIG. 8 shows that for deposition processes occurring at 510° C. or 540° C., a decrease in face plate-to-wafer spacing results in an increase in deposition rate. This relationship is more pronounced at closer face plate-to-wafer spacings.

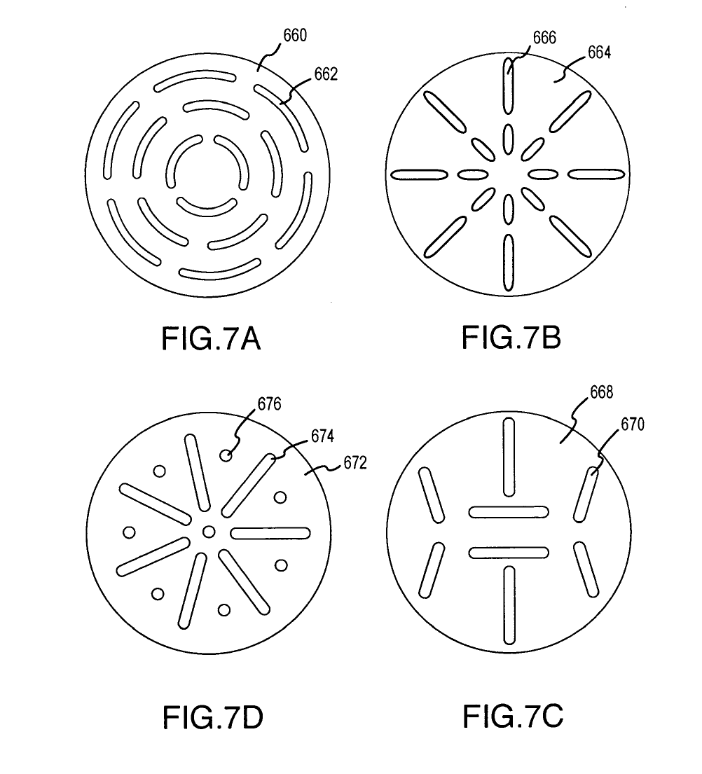

FIG. 9 plots USG deposition rate over a broader range (50-250 mils) of face plate-to-wafer spacings. FIG. 9 confirms the results of FIG. 8 over this broader range. Specifically, FIG. 9 indicates an increase in USG deposition rate at closer spacings, and also indicates a more pronounced effect upon deposition rate at closer spacings.

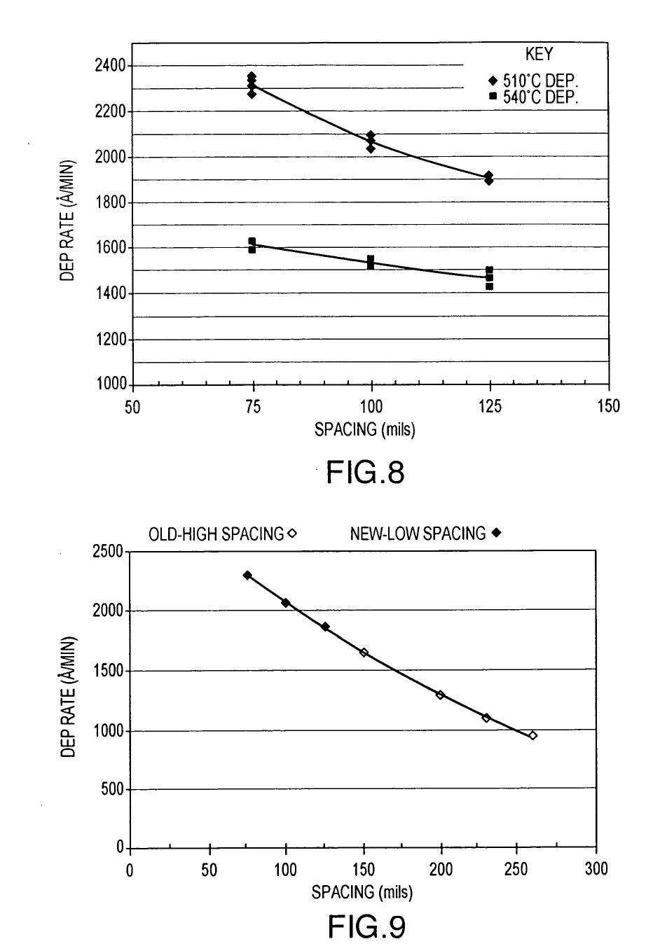

FIG. 10 plots % film shrinkage and wet etch selectivity versus face plate-to-wafer spacing for USG deposition processes at different temperatures and pressures. FIG. 10 indicates that USG films deposited at both 510° C. and 540° C. exhibited low shrinkage when deposited at close face plate-to-wafer spacings. This data indicates formation of a denser higher quality film at close spacings.

The wet etch data of FIG. 10 correlates this finding of improved quality of layers deposited at close face plate-to-wafer spacings. Specifically, USG films deposited at closer face plate-to-wafer spacings exhibited a wet etch selectivity consistent with higher density.

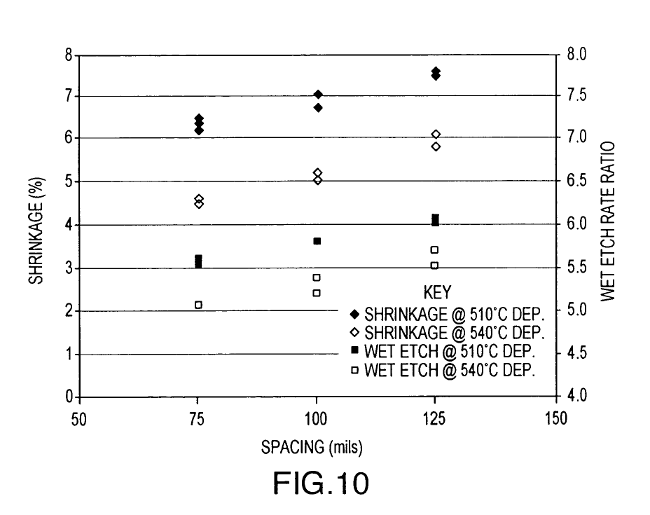

FIGS. 11A and 11B show photographs of cross-sections of shallow trench isolation structures formed by high temperature USG deposition utilizing a showerhead in accordance with the present invention. The USG deposition process shown in FIGS. 11A and 11B took place at temperatures of 510° C., with face plate-to-wafer spacings of 75 mils. The photographs show the USG filled shallow trench structures after a post-deposition anneal at 1050° C. for 60 min. FIGS. 11A and 11B show that a comparable quality in gap fill is achieved with the process in accordance with embodiments of the present invention as compared with processes employing conventional face plate designs.

B. Tapered Faceplate

Embodiments in accordance with the present invention are also not limited to the utilization of a slotted showerhead face plate. Returning to FIG. 4A, one consequence of the close proximity of showerhead 308 relative to wafer 302 may be an increase in downward flow of process gases near the edges of the wafer. The resulting increase in mass flow to the wafer edges may give rise to increased edge thickness 320a of deposited material 320.

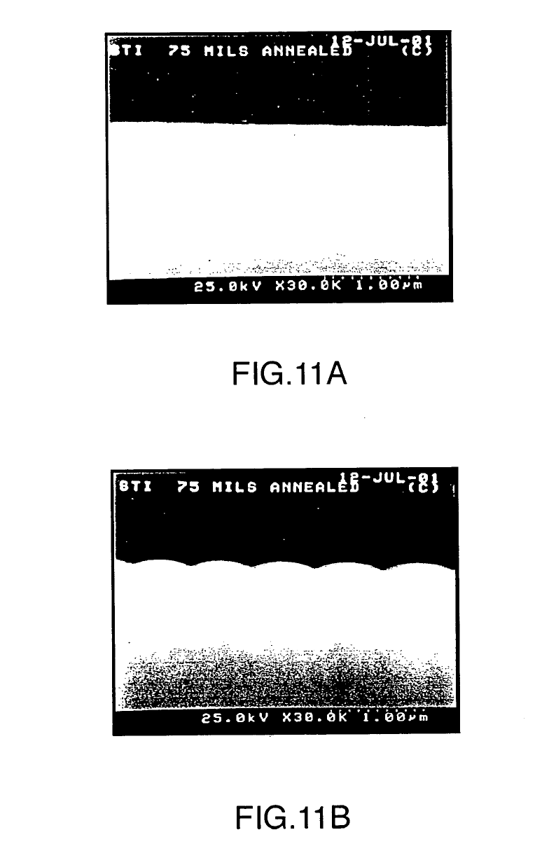

FIG. 12 plots calculated added mass flow versus distance from the center of the wafer for two face plate-to-wafer spacings. At the conventional wide face plate-to-wafer spacing of 0.270″, the deposition added mass flow that is relatively consistent from the center of the wafer to the edge. However, at a narrower face plate-to-wafer spacing of 0.075″, the process exhibits a marked additional mass flow to peripheral regions of the wafer. This added mass flow may create a layer of deposited material having significantly greater thickness at its edges than at the center.

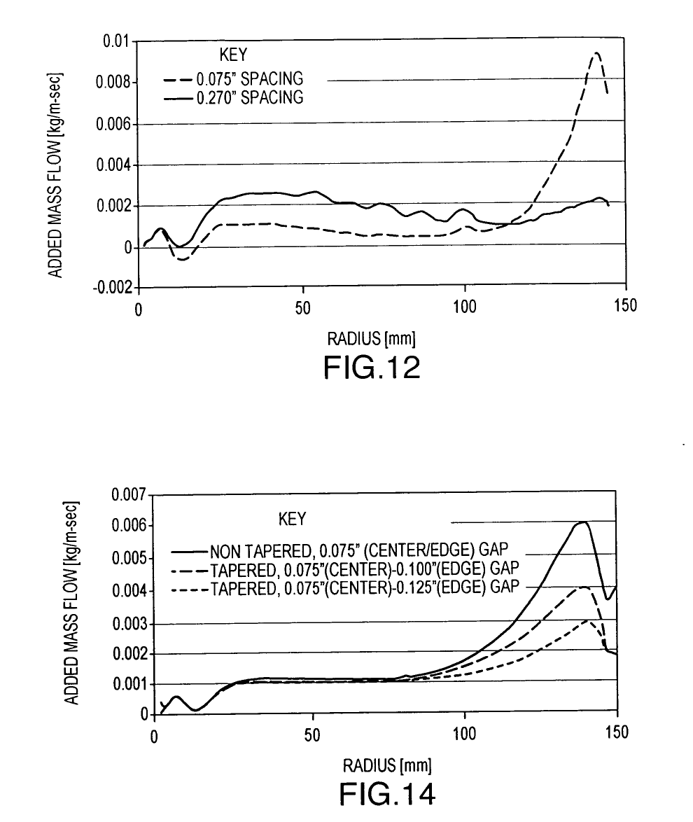

Accordingly, an alternative embodiment of a showerhead of the present invention may use a face plate having a tapered profile to avoid increased edge thickness of deposited materials at close face plate-to-wafer spacings. FIG. 13 shows a simplified cross-sectional view of an alternative embodiment of a high temperature deposition system in accordance with the present invention. Apparatus 900 comprises wafer 902 in contact with wafer support structure 904 and positioned within deposition chamber 906. Gas distribution showerhead 908 is positioned above wafer 902 and is separated from wafer 902 by gap Y″.

Gas distribution showerhead 908 comprises process gas inlet 912 in fluid communication with blocker plate 914 having apertures 916. Gas distribution face plate 918 is positioned downstream of blocker plate 914. Face plate 918 receives a flow of process gas from blocker plate 914 and flows this gas through holes 920 to wafer 902.

As described above in connection with FIG. 4A, the close proximity of the face plate relative to the wafer may result in an enhanced flow of mass to the edges of the wafer. Accordingly, the embodiment shown in FIG. 13 includes face plate 918 having a tapered profile. Specifically, edge portion 918a of face plate 918 is recessed relative to center portion 918b of face plate 918. Taper angle A represents the angle defined by the difference in thickness between face plate center and edge, and may range from about 0.5° to about 5°.

The use of a gas distribution showerhead featuring an improved thickness uniformity of deposited materials at close face plate-to-wafer spacings. TABLE A compares deposition rate, thickness uniformity, and thickness range for materials deposited at spacings of 100 and 75 mils, by tapered and flat face plates.

TABLE A

| GAP | TAPERED FACEPLATE | | | FLAT FACEPLATE | | |
|---|---|---|---|---|---|---|
| SPACING | Dep. Rate | | | Dep. Rate | | |
| (mils) | (Å/min) | 1 σ unif | Range | (Å/min) | 1 σ unif | Range |
| 75 | 1950 | 7.3 | 12.7 | 2000 | 13.4 | 20.5 |
| 100 | 1600 | 4.6 | 7.6 | 1890 | 8.7 | 13.3 |

TABLE A indicates that deposition utilizing the tapered face plate results in formation of a layer of material having a more uniform center-to-edge thickness. While the data collected in TABLE A reflects deposition utilizing tapered and flat face plates having elongated slots, tapered face plates in accordance with embodiments of the present invention are not required to have elongated slots.

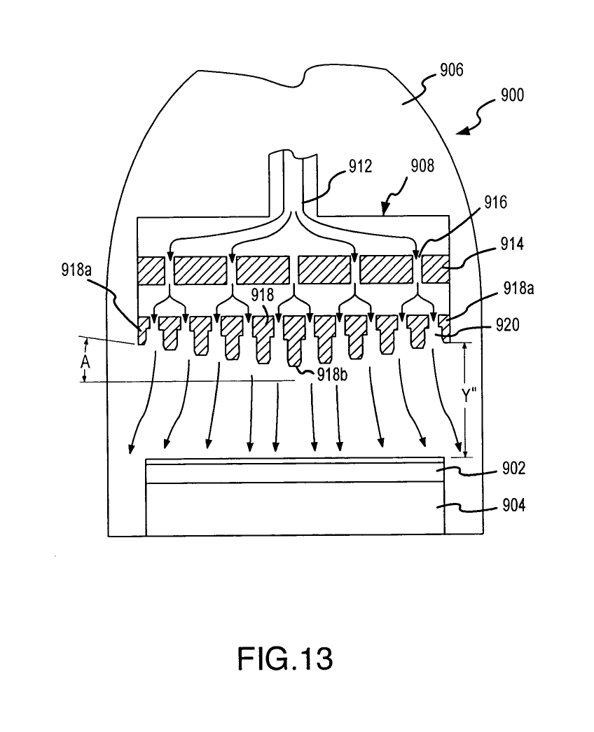

FIG. 14 plots calculated added mass flow versus distance from the center of the wafer for three different face plate profiles. FIG. 14 shows that the peak-to-valley variation in added mass across the wafer was reduced by 35% and 46% by tapering the gap by 0.025″ and 0.050″, respectively. The use of tapered face plate structures in accordance with embodiments of the present invention may result in deposition of material layers exhibiting a variation in center-to-edge thickness of 800 Å or less.

C. Reduced Width of Faceplate Inlet Orifice

The above description has focused upon the presence of outlet faceplate slots and/or the use of a tapered faceplate profile to ensure thickness uniformity in films deposited at close faceplate-to-wafer spacings. However, other techniques may be employed to ensure the uniformity in thickness of deposited films over a broad range of faceplate-to-wafer spacings.

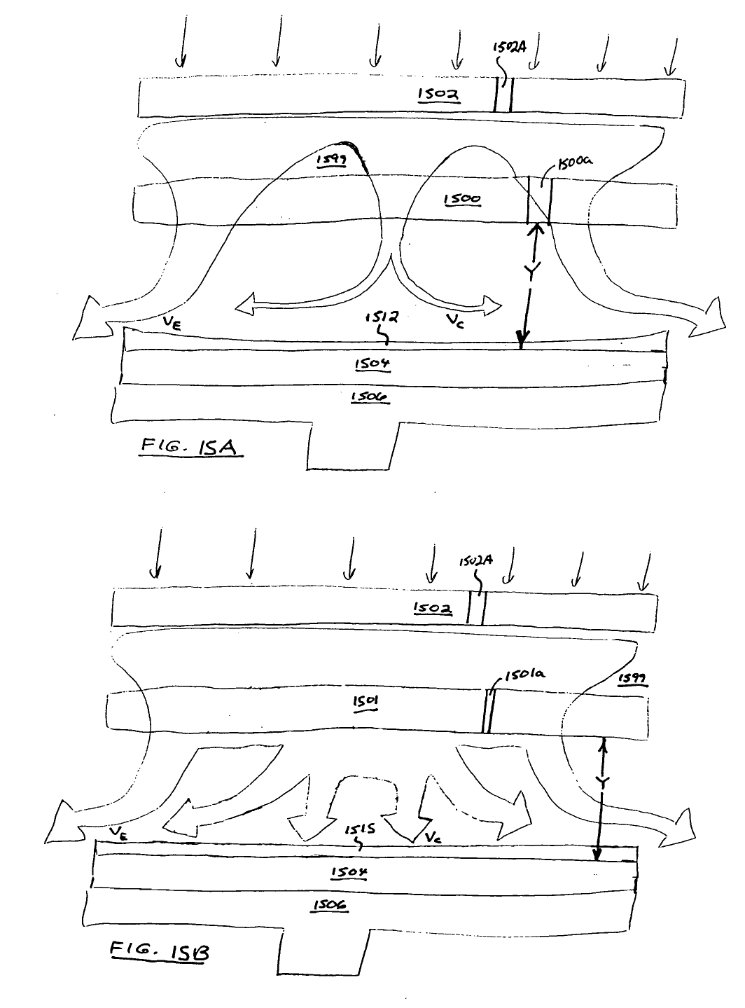

FIG. 15A shows a simplified schematic diagram illustrating the effect of process gas flow velocity and pressure across edge and center regions of a conventional gas distribution faceplate 1500 positioned downstream of a blocker plate 1502. Specifically, wafer 1504 is supported on heater 1506 that is separated from overlying faceplate 1500 by spacing Y.

Process gas flows initially through orifices 1502A in blocker plate 1502 to region 1599 upstream of faceplate 1500. The process gas then flows through orifices 1500a in distribution faceplate 1500 across gap 1510 of length Y to the surface of wafer 1504, thereby depositing film 1512.

The thickness of deposited film 1512 is dependent upon localized gas velocities reaching the wafer surface. Gas flowing through the edge of the showerhead to the edge of the wafer encounters a relatively low resistance flow path to the chamber outlet. By contrast, gas flowing through the center of the showerhead to the center of the wafer encounters a higher resistance flow path, as it stacks up behind the wafer edge gases flowing out of the chamber. Variation in thickness of the deposited film between the wafer center and edge may be attributed primarily to the different velocities of gas passing through the faceplate edge (V_{E}) versus velocities of gas passing through the faceplate center (V_{C}). These gas flow velocities V_{E} and V_{C} in turn depend upon the differing pressure drop across the center and edge regions of the faceplate.

A simplified relationship between gas velocity and pressure is given by Equation (1) below:

V=KP, where: (1)

V=gas velocity;

K=constant; and

P=pressure.

An expression for the magnitude of variation in gas flow velocity is given in Equation (2):

$$\begin{matrix}\% Δ V = Δ V / {V}_{avg} \\ = Δ {P}_{R} / Δ {P}_{FP} \\ = \frac{{CV}_{avg} ( 1 / {L}^{2} )}{{C}^{′} ( {V}_{avg}^{2} / {d}^{4} )} , where\end{matrix} \qquad ( 2 )$$

% ΔV=percentage change in velocity from wafer center to edge;

Δ=change in velocity from wafer center to edge;

V_{avg}=average velocity between wafer center and edge;

ΔP_{R}=change in pressure from wafer center to edge;

ΔP_{FP}=change in pressure across faceplate from center to edge;

C=first constant;

C′=second constant;

Y=showerhead to wafer spacing; and

d=diameter of faceplate orifice.

Equation (2) may in turn be simplified to read:

$$\% DV = \frac{{C}^{″} {d}^{4}}{{Y}^{2} {V}_{avg}} , where \qquad ( 3 )$$

% ΔV=percentage change in velocity from wafer center to edge;

V_{avg}=average velocity between wafer center and edge;

C″=combined constant (from first and second constants);

Y=showerhead to wafer spacing; and

d=diameter of faceplate orifice.

Equation (3) suggests a number of possible approaches to reduce variation in gas velocity (% ΔV). One approach is to increase faceplate-to-wafer spacing (Y). However, this may be impractical due to constraints in the process, such as the need for high deposition rates leading to correspondingly high tool throughput.

Another possible technique suggested by Equation (3) for reducing % ΔV is to increase the average flow rate (V_{avg}). However, this approach may also be impractical due to constraints in existing hardware architecture of the tool, for example feed pipe diameters limiting gas velocities to below certain levels.

Equation (3) suggests that a third possible technique for reducing % ΔV is to reduce the diameter (d) of orifices in the faceplate, thereby increasing the pressure drop across the faceplate. This approach is illustrated schematically in FIG. 15B, a simplified cross-sectional view illustrating the flow of gas through a gas distribution faceplate 1501 having inlet orifices 1501 a of reduced size in accordance with an embodiment of the present invention. FIG. 15B shows that reduction in the width of orifices inlet to the faceplate constricts a flow of processing gases through the faceplate, creating increased pressure in region 1599 immediately upstream of the faceplate. This upstream pressure increase in turn limits the velocity of gases flowed across the faceplate, creating a pressure drop and a low pressure region between the faceplate and the wafer, with gases over wafer edge and center regions exhibiting more uniform velocities. In this manner, the reduced flow resistance experienced by gases encountering the wafer edge plays less of a role in determining overall gas flow.

Thus in the embodiment of the present invention illustrated in connection with FIG. 15B, overall gas flow velocities are governed by the pressure drop across the entire faceplate. By contrast, in the conventional faceplate illustrated in connection with FIG. 15A, the overall flow of gas is governed by differences in pressure drop experienced by gas flowing to the wafer edge, as opposed to the wafer center. In the former case, material is deposited on the wafer center and edge at more uniform rates.

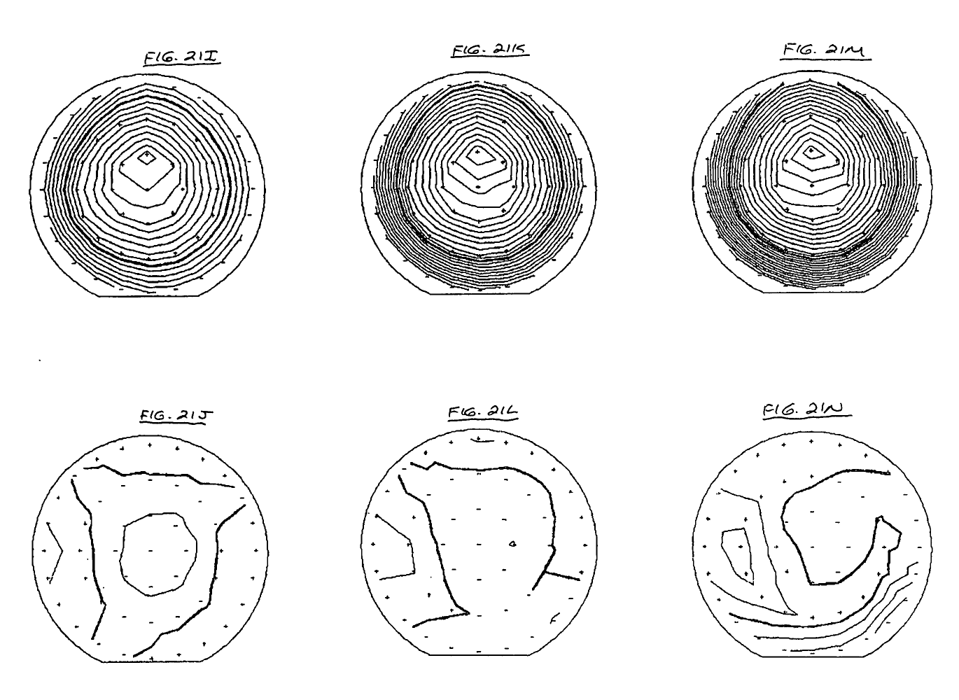

FIGS. 21A-N show thickness uniformity maps for a plurality of 300 mm wafers bearing layers deposited utilizing a conventional low gas flow resistance faceplate having an inlet diameter of 29 mils, and for a plurality of 300 mm wafers bearing layers deposited utilizing a higher gas flow resistance faceplate in accordance with an embodiment of the present invention, having an inlet diameter of 10 mils. TABLE B below summarizes these results.

TABLE B

| FACEPLATE TO | | | | |
|---|---|---|---|---|
| WAFER | FIGURE | INLET ORIFICE | 1σ | (Edge/ |
| SPACING (mil) | NO. | WIDTH (mil) | (%) | Center) * 100 |
| 60 | 21A | 29 | 10.3 | 122.1 |
| | 21B | 10 | 3.92 | 107.3 |
| 75 | 21C | 29 | 3.18 | 104.9 |
| | 21D | 10 | 2.26 | 102.8 |
| 100 | 21E | 29 | 2.62 | 98.8 |
| | 21F | 10 | 2.36 | 103.5 |
| 125 | 21G | 29 | 1.54 | 96.9 |
| | 21H | 10 | 1.70 | 102.2 |
| 260 | 21I | 29 | 3.78 | 91.5 |
| | 21J | 10 | 0.64 | 101.5 |
| 350 | 21K | 29 | 4.99 | 90.7 |
| | 21L | 10 | 0.63 | 100.8 |
| 450 | 21M | 29 | 5.59 | 88.2 |
| | 21N | 10 | 1.01 | 99.8 |

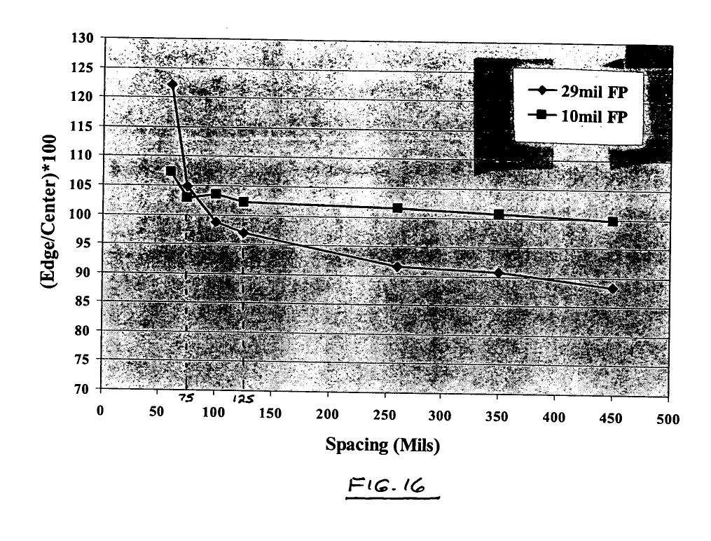

FIG. 16 plots the ratio of edge/center thickness (×100) versus faceplate-to-wafer spacing for the results given above in TABLE B. FIG. 16 shows that reduction in the diameter of the orifices of the faceplate resulted in a more consistent thickness of the film deposition from the wafer center to edge over a much wider range of wafer-to-faceplate spacings. Specifically, the faceplate having orifices of diameter 0.010″ in accordance with the present invention exhibited a variation within about 3% over a spacing range of between about 75 and 450 mils. By contrast, the conventional faceplate having orifices of diameter 0.029″ exhibited a 3% thickness variation only within a much smaller spacing range of between about 90-125 mils.

Moreover, over this smaller spacing interval the value of the edge/center ratio for the conventional face plate varied over the full ±3% (6% total) range. By contrast, for the faceplate in accordance with an embodiment of the present invention, the edge/center ratio remained greater than 100%, within a narrower (+3%) total range.

While the example just described relates to the use of inlet orifices having a width of 0.010″, embodiments of faceplate structures in accordance with the present invention are not limited to inlet orifices of this or any other particular size. For example, the difficulty and added expense associated with having to fabricate additional numbers of inlet orifices may be reduced by utilizing a faceplate design having a fewer number of slightly larger holes.

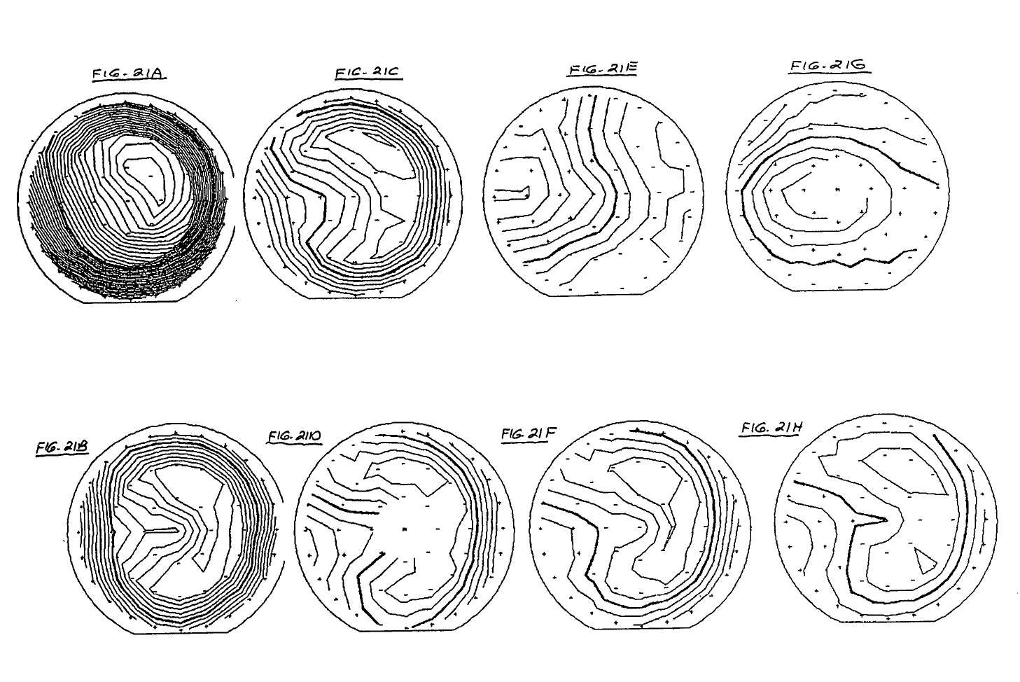

Accordingly, FIGS. 20A-B show performance characteristics of a faceplate design having inlet orifices of width 0.012″. FIG. 20A plots pressure drop versus the number of inlet orifices for a face plate design. FIG. 20B plots gas velocity at the top of a slot versus the number of inlet orifices.

FIG. 20A shows that control over the desired pressure drop across the faceplate can be achieved by limiting the number of inlet orifices. FIG. 20B shows that the velocity of gas at the top of the slot for a faceplate of orifices of 0.012″ diameter matches that of a faceplate having 0-010″ diameter inlet orifices, where the 0.012″ diameter orifices number about 10,000.

TABLE C below compares the attributes of conventional low gas flow resistance faceplates and faceplates in accordance with the present invention, as used to process 300 mm diameter substrates.

TABLE C

| PROCESSED | INLET | NUMBER | ESTIMATED |
|---|---|---|---|
| WAFER | ORIFICE | OF INLET | PRESSURE DROP |
| DIAMETER (mm) | WIDTH (mil) | ORIFICES | (Torr) |
| 300 | 29 mil | 7500 | 0.2-0.3 |
| 300 | 10 mil | 14500 | 0.8-1.0 |
| 300 | 12 mil | 10000 | 0.8-1.0 |
| 200 | 29 mil | 2977 | 0.2-0.3 |
| 200 | 10 mil | 5491 | 0.8-1.0 |
| 200 | 12 mil | 4141 | 0.8-1.0 |

D. Reduction in Depth of Faceplate Inlet Orifices

As described previously in connection FIGS. 15A-B and Equations (1)-(3), it may be advantageous to elevate the pressure drop across the faceplate in order to ensure even gas flow velocities across center and edge portions of the faceplate, with resulting even deposition of material on center and edge portions of the wafer surface. The configuration of the faceplate inlet orifice may also affect the character of material deposited utilizing the faceplate.

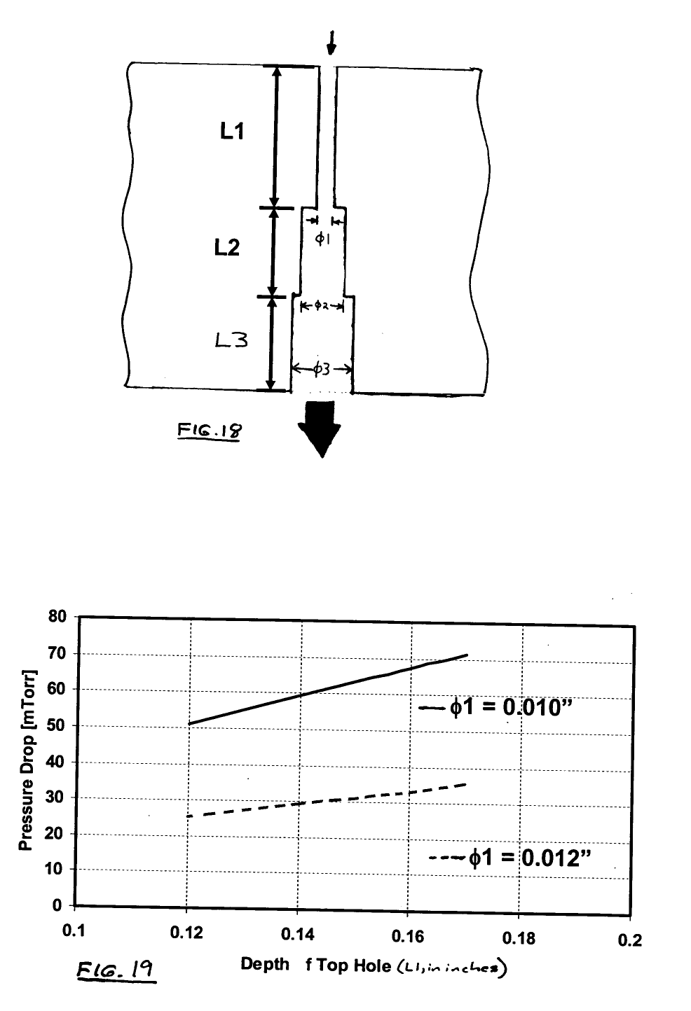

FIG. 18 shows a cross-sectional view of a portion of one embodiment of a faceplate in accordance with the present invention. Faceplate 1800 includes inlet orifice 1802 of width φ1 and depth L1, in fluid communication with outlet slot 1804 of width φ3 and depth L3, through intermediate orifice portion 1806 having width φ2 and depth L2. In the embodiment shown in FIG. 18, the presence of the intermediate orifice portion 1806 is attributable primarily to limitations in the ability of current machining technology to fabricate an orifice of the narrow width φ1 having the full depth of L1+L2., which is 0.025″ in the case of one embodiment of a faceplate utilized to deliver gases above the surface of a 300 mm-diameter wafer.

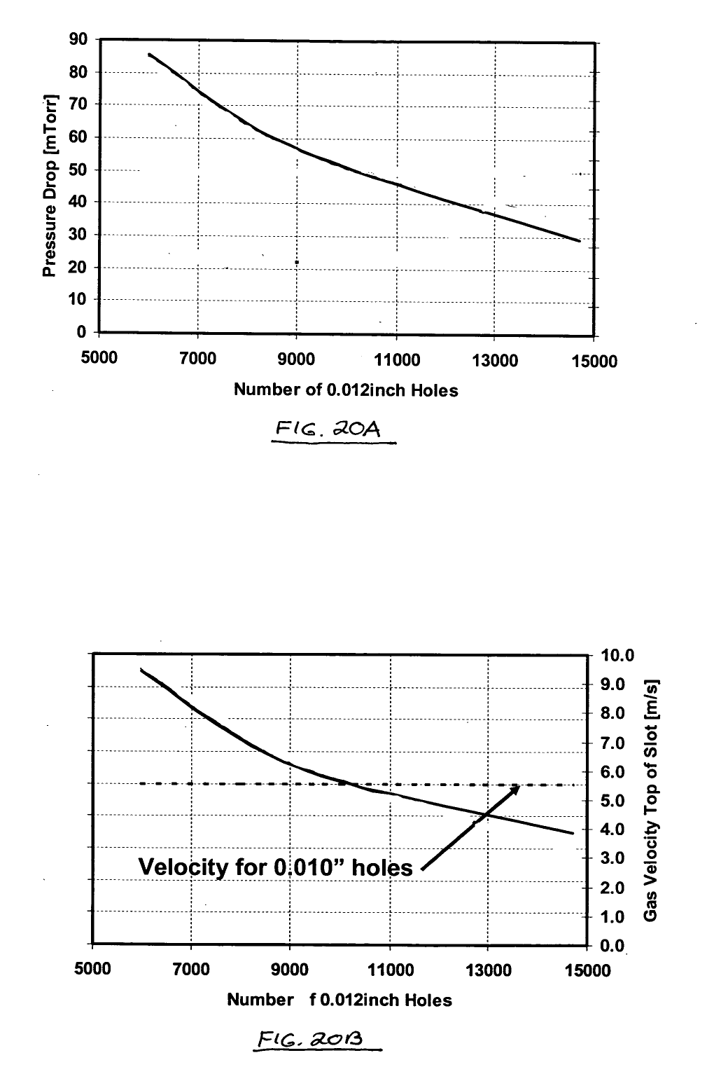

FIG. 19 plots the pressure drop across a faceplate versus the depth of the inlet hole (L1), for two different faceplate designs having inlet orifices of width (φ1) of 0.010″ and 0.012″, respectively. FIG. 19 shows that for both faceplate designs, increasing the depth (L1) of the inlet orifice resulted in an increase in the pressure drop across the faceplate. FIG. 19 also shows that decreasing width of the inlet hole desirably increased the pressure drop across the faceplate. Either or both of these techniques may be utilized to ensure even gas flow velocities between the center and edge portions of the faceplate, resulting in homogeneous rates of deposition of material at the center and edge of a wafer.

Only certain embodiments of the present invention are shown and described in the instant disclosure. One should understand that the present invention is capable of use in various other combinations and environments and is capable of changes and modification within the scope of the inventive concept expressed herein. For example, apparatuses and methods in accordance with embodiments of the present invention are not limited to processing semiconductor wafers of any particular size, and are useful for semiconductor fabrication processes involving 200 mm diameter wafers, 300 mm diameter wafers, or semiconductor wafers of other shapes and sizes.

And while embodiments in accordance with the present invention have been described so far in connection with the flow of silicon-containing precursor gases employed in high temperature deposition of undoped silicate glass, the invention is not limited to this particular embodiment. A showerhead in accordance with embodiments of the present invention may be used to distribute a wide variety gases useful in an array of semiconductor fabrication processes, including but not limited to the chemical vapor deposition of doped silicon oxide in the form of phosphosilicate glass (PSG), borosilicate glass (BSG), or borophosphosilicate glass (BPSG).

Examples of gases that may be distributed utilizing a showerhead in accordance with an embodiment of the present invention include, but are not limited to, tetraethylorthosilane (TEOS), triethylphosphate (TEPO), and triethylborate (TEB). The invention is not limited to distributing the flow of precursor gases, and could be used to flow carrier gases such as He and N₂ that do not directly participate in a CVD reaction.

A showerhead in accordance with embodiments of the present invention may also be used to flow precursor gases for the formation of materials other silicon oxides, including but not limited to metals, nitrides, and oxynitrides. And while the showerhead is described above in conjunction with a high temperature CVD process, embodiments in accordance with embodiments of the present invention may be utilized to flow gases in other types of CVD processes, such as plasma enhanced chemical vapor deposition (PECVD) processes or subatmospheric chemical vapor deposition (SACVD) processes.

Embodiments in accordance with the present invention are also not limited to use in conjunction with chemical vapor deposition processes. Showerheads in accordance with the present invention may also be employed to flow gases in other types of semiconductor fabrication processes, such as dry or plasma etching processes.

Given the above detailed description of the present invention and the variety of embodiments described therein, these equivalents and alternatives along with the understood obvious changes and modifications are intended to be included within the scope of the present invention.

What is claimed is:

1. A gas distribution face plate comprising:
a face plate body having a thickness defining a number of inlet orifices having a width and a depth, at least one of the number, the width, and the depth configured to create a uniform pressure drop of between about 0.8 and 1 Torr across edge and center regions of the faceplate as gas is flowed through the inlet orifices, whereby a thickness of material deposited at an edge of a wafer varies by 3% or less from a thickness of material deposited at a center of the wafer, when the wafer is separated from the face plate by a gap of between about 75 and 450 mils.

2. The face plate of claim 1 wherein the orifice width comprises between about 0.010″ and 0.018″.

3. The face plate of claim 1 wherein the number comprises between about 2000 and 17500 orifices.

4. The faceplate of claim 3 wherein the number comprises about 10000 and the face plate is configured to process a wafer having a diameter of about 300 mm.

5. The faceplate of claim 3 wherein the number comprises about 5000 and the face plate is configured to process a wafer having a diameter of about 200 mm.

6. A method of depositing on a semiconductor wafer, a layer of material having a center-to-edge thickness variation of 3% or less, the method comprising:
providing a gas distribution faceplate having a thickness and defining a number of inlet orifices having a width and a depth, at least one of the orifice number, width, and depth configured to create a uniform pressure drop of between about 0.8 and 1 Torr as gas is flowed through edge and center regions of the faceplate;
providing a semiconductor wafer separated from the gas distribution faceplate by a gap; and
flowing a gas through the faceplate body and across the gap to deposit the layer of material on the wafer.

7. The method of claim 6 wherein the semiconductor wafer is provided at a gap of between about 75 and 450 mils.

8. The method of claim 6 wherein the faceplate body is provided with orifices having a width of between about 0.010″ and 0.018″.

9. The method of claim 6 wherein the face plate body is provided with between about 2000 and 17500 orifices.

10. The method of claim 9 wherein a 300 mm diameter wafer is provided, and the faceplate is provided with about 10000 orifices.

11. The method of claim 9 wherein a 200 mm diameter wafer is provided, and the faceplate is provided with about 5000 orifices.

12. A method of promoting deposition of material of uniform center-to-edge thickness on a semiconductor wafer, the method comprising:
constricting a flow of deposition gas through a gas distribution faceplate, such that a resulting pressure drop across the faceplate creates a low pressure region over a wafer, gas velocities in the low pressure region over a wafer center and a wafer edge sufficiently uniform to result in deposition of a layer of material having a center-to-edge thickness variation of 3% or less.

13. The method of claim 12 wherein the resulting pressure drop is between about 0.8 and 1.0 Torr.

14. The method of claim 12 wherein the semiconductor wafer is provided at a gap of between about 75 and 450 mils from the faceplate.

15. The method of claim 12 wherein the deposition gas flow is constricted by faceplate orifices having a width of between about 0.010″ and 0.018″.

16. The method of claim 12 wherein the deposition gas flow is constricted by faceplate orifices numbering between about 2000 and 17500.

17. The method of claim 16 wherein the deposition gas flow is constricted by about 10000 orifices and the material is deposited on a 300 mm diameter wafer.

18. The method of claim 16 wherein the deposition gas flow is constricted by about 5000 orifices and the material is deposited on a 200 mm diameter wafer.
